(19) United States
(12) Patent Application Publication
(10) Pub. No.: US 2008/0251848 A1
(43) Pub. Date: Oct. 16, 2008

(54) Manufacturing method for homogenizing the environment of transistors and associated device

(75) Inventors: Bertrand Borot, Le Cheylas (FR); Richard Ferrant, Esquibien (FR)

Correspondence Address: DOCKET CLERK, P.O. DRAWER 800889, DALLAS, TX, 75380, US

(73) Assignee: STMicroelectronics (Crolles2) SAS, Crolles (FR)

(21) Appl. No.: 12/082,630

(22) Filed: Apr. 11, 2008

(30) Foreign Application Priority Data
Apr. 12, 2007 (FR) 07-54397

(51) Int. Cl. H01L 29/00; H01L 21/336

(52) U.S. Cl. 257/365; 438/279; 257/E21.409; 257/E29.001

(57) ABSTRACT

A semiconductor device is provided that includes a plurality of patterns. Each pattern includes at least one field effect transistor. Each field effect transistor includes a source region, a drain region, a channel region, and a gate region formed above the channel region. A portion of the plurality of patterns is formed in a single active area of a semiconductor substrate, where the area delimited by an isolation region. One of the source region and the drain region of each adjacent pattern are formed in said active area.

### CROSS-REFERENCE TO RELATED APPLICATIONS

The present application is related to French Patent Application No. 07-54397, filed Apr. 12, 2007, entitled “MANUFACTURING METHOD FOR HOMOGENIZING THE ENVIRONMENT OF TRANSISTORS AND ASSOCIATED DEVICE”. French Patent Application No. 07-54397 is assigned to the assignee of the present application and is hereby incorporated by reference into the present disclosure as if fully set forth herein. The present application hereby claims priority under 35 U.S.C. §119(a) to French Patent Application No. 07-54397.

### TECHNICAL FIELD

The present invention relates to the field of microelectronics and more particularly to the manufacture of transistors.

### BACKGROUND

Increasing the density of integration of transistors into active devices is an aim of the microelectronics industry. However, in a highly competitive market, there is a need to improve the quality and the homogeneity of integration so as to maintain a certain profitability.

During the manufacture, for example of processors, the devices are generally sorted according to the number of transistors that are functional in relation to the expected number. According to the ratio of functional transistors, the devices are split into batches, classed according to their performances and sold at different prices, despite being produced with the same manufacturing methods.

Such practices, which are necessary to make the whole of a production profitable, nevertheless incur a certain loss of earnings. To optimize uniformity of the performances of transistors, the physical modelling of transistors has recently gained in importance. This trend has also become more pronounced with the development of the latest fine etching technologies, wherein sensitivity to the environment is heightened.

The microelectronics industry is beginning to design architectures based on components with standardized patterns so as to standardize performances.

Several sources of divergence in performance have thus been identified, among which are the STI (Shallow Trench Isolation) lateral isolation trench stress, the proximity effects of the doped casings and the rounding of the pattern edges.

The lateral isolation trench stress is manifested in source and drain region lengths which do not match the dimensions set out during the design stage. The new lengths of the source and drain regions modify the performances of the transistor.

The proximity effects of the doped casings appear during the implantation stage and modify the extension of effective doping of the active areas.

The pattern edge rounding effect appears in geometries having a number of angles and a high density of objects, by changing the pattern geometry which is obtained during lithography in relation to the expected pattern geometry.

### SUMMARY

In view of the above, it is proposed to homogenize the environment of each transistor of a semiconductor device including a set of patterns each formed by at least one field effect transistor, so as to limit the influence of the harmful effects of the structure of a device on the performances of said device.

It is also proposed to limit the divergence in the performances of the transistors on such a device.

It is further proposed to limit the occurrence of lateral isolation trench stress and of pattern edge rounding, and to standardize the effect of the casings on all of the transistors of a device.

Thus, according to one aspect of the device, at least part of the patterns is formed in a single active area of a semiconductor substrate, the area being delimited by an isolation region, such that the source or drain regions of each adjacent pattern are formed in said active area.

In an embodiment, the patterns can be laid out in the form of lines, the drain and source regions of a single line having the same dimensions and being spaced apart by gate regions with fixed dimensions.

In an embodiment, two source and/or drain regions of a single line which are separated by a distance that is equal to the size of a gate and which are biased according to the same potential can share the same active region.

Each line can include at least one additional end transistor at each end. Each block can include additional end lines.

The device can furthermore include at least one junction located between two adjacent active areas having different polarities. Each junction can include a gate.

According to another aspect, a method is also proposed for manufacturing semiconductor devices including a set of patterns each formed by at least one field effect transistor each including a source region and a drain region delimiting, between them, a channel region and a gate region formed above the channel region.

In an embodiment, at least a part of the patterns is formed in a single active area of a semiconductor substrate, the area being delimited by an isolation region, such that the source or drain regions of each adjacent pattern are formed in said active area.

The patterns can be produced in the form of lines, the drain and source regions having the same dimensions within a single line, the drain and source regions being spaced apart by gate regions with fixed dimensions.

At least one junction can be formed between two adjacent active areas having different polarities. The junction can be formed by producing a gate between said active areas. Furthermore, at least one additional end transistor can be produced at the ends of each line.

Aspects of the disclosure may be found in a semiconductor device that includes a plurality of patterns. Each pattern includes at least one field effect transistor. Each field effect transistor includes a source region, a drain region, a channel region, and a gate region formed above the channel region. A portion of the plurality of patterns is formed in a single active area of a semiconductor substrate, where the area delimited by an isolation region. One of the source region and the drain region of each adjacent pattern are formed in said active area.

Other aspects of the disclosure may be found in a method of manufacturing a semiconductor device. The method includes forming a plurality of patterns in a semiconductor substrate. Each pattern comprises at least one field effect transistor, where each field effect transistor includes a source region, a drain region, a channel region, and a gate region formed above the channel region. A portion of the plurality of patterns is formed in a single active area of the semiconductor substrate, where the area delimited by an isolation region. One of the source region and the drain region of each adjacent pattern are formed in the active area.

Further aspects of the disclosure may be found in a semiconductor device that includes an isolation region and a plurality of patterns. Each pattern includes at least one field effect transistor. Each field effect transistor includes a source region, a drain region, a channel region, and a gate region formed above the channel region. A portion of the plurality of patterns is formed in a single active area of a semiconductor substrate, where the area delimited by the isolation region. One of the source region and the drain region of each adjacent pattern are formed in said active area.

Other technical features may be readily apparent to one skilled in the art from the following figures, descriptions and claims.

### BRIEF DESCRIPTION OF THE DRAWINGS

For a more complete understanding of this disclosure and its features, reference is now made to the following description, taken in conjunction with the accompanying drawings, in which:

FIG. 1 illustrates a situation linked to the presence of an isolation trench stress;

FIG. 2 illustrates the influence of the doping wells;

FIGS. 3a and 3b illustrate a pattern-rounding situation;

FIG. 4 shows a first exemplary embodiment of a semiconductor device according to an aspect of the invention; and

FIG. 5 shows a second exemplary embodiment of a semiconductor device according to an aspect of the invention for a set of different bias voltages.

### DETAILED DESCRIPTION

In a conventional manufacturing method, lateral isolation trenches are created and delimit an area wherein the active region will be formed. The active region is then manufactured by doping. A stress can affect the lateral isolation trenches resulting in a change in the shape of the active region.

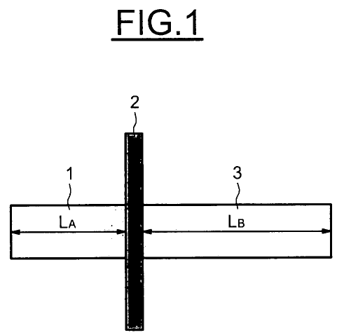

Thus, referring to FIG. 1, a stress of at least one lateral isolation trench can cause a change in the lengths of the source 1 and drain 3 regions in relation to the expected values.

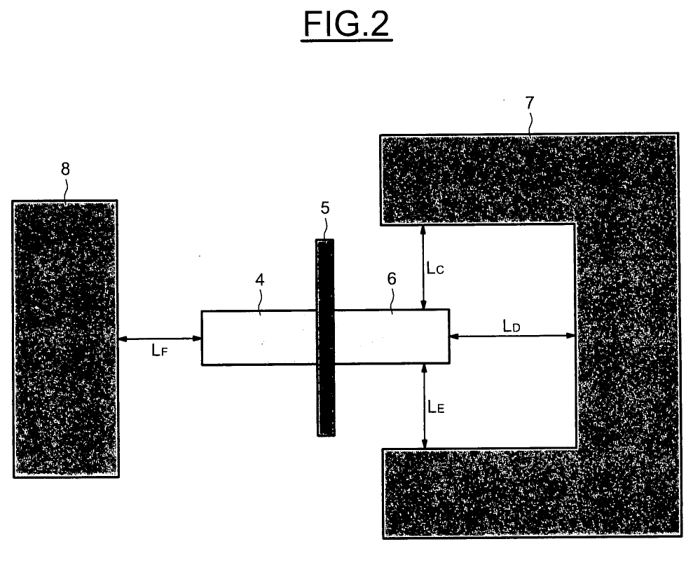

Proximity effects of the doped casings appear during the implantation stage. Depending on the presence or absence of doped casings proximate to the source and drain regions of the transistor, the doses received by these regions vary. Indeed, during implantation, a protective layer is deposited on the doped casings. A part of the implantation ion flux rebounds off the vertical surface of this protective layer. Depending on the distance between the doped casings and the active region of the transistor, the dose implanted in the active region can be increased, or the active region further extended, or both. FIG. 2 illustrates the proximity effects of the doped casings. This figure shows a transistor including a gate 5, a drain region 4 and a source region 6, which is surrounded by two doped casings 7 and 8. The doped casing 8 is placed opposite the drain region 4. During implantation, the ion flux that rebounds off the protective layer of the doped casing 8 can change the length of the drain region 4 as a result of the positions of the two structures. In the case of the doped casing 7 and the source region 6, the geometry of both structures may change the width and the length of the source region 6. Indeed, at least a part of the doped casing 7 is positioned opposite each face of the source region 6. Each face can therefore be affected. By contrast, the doped casing 8 may only affect one side of the drain region 5.

The pattern edge-rounding effect appears in geometries having numerous angles and a high density of objects. As a result of proximity effects and migration of the active species of the photoresists, the angle areas and pattern high density areas are less well defined.

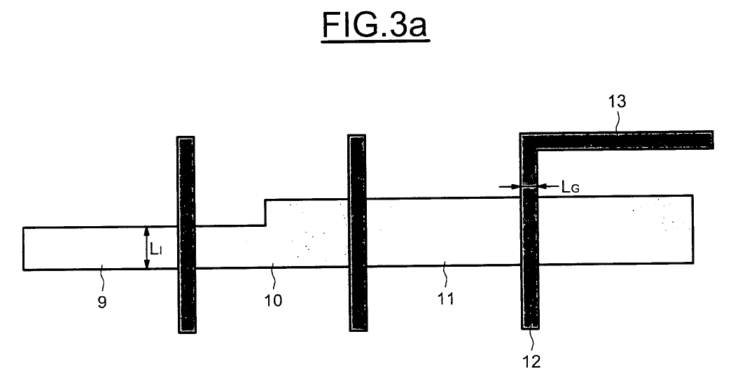

FIGS. 3a and 3b illustrate two of these cases. FIG. 3a shows the perfect case as set out during design. As can be seen, FIG. 3a illustrates three junctions each having at least a shared source or drain region with the adjacent junction.

Furthermore, the regions 9 and 11 do not have the same width, a change in size taking place in the region 10. Also, the gate 12 is connected at a right angle with the contact line 13.

FIG. 3b shows the same device as that illustrated in FIG. 3a but subject to a pattern-rounding effect. More particularly, the area 14 has a concave profile instead of a right angle profile. During photolithography, the illumination dose is calculated such that the photosensitivity threshold is only reached in the desired areas, in this case the parallelepipeds defining the gate 12 and the contact line 13. However, the illumination profile decreases gradually with distance around an illuminated area. Thus, in the area 14 which is delimited by the intersection of the two parallelepipeds, the overlap of the two illumination profiles creates an area which exceeds the photosensitivity threshold. During the pattern transfer stages, this area will be transferred in the same way as the two parallelepipeds defining the gate 12 and the contact track 13. Thus, instead of a contact line being produced at a right angle with the gate, the concave area 14 is produced.

The same phenomenon can be seen in the area 15 where the series of two right angles is smoothed off due to the proximity effects.

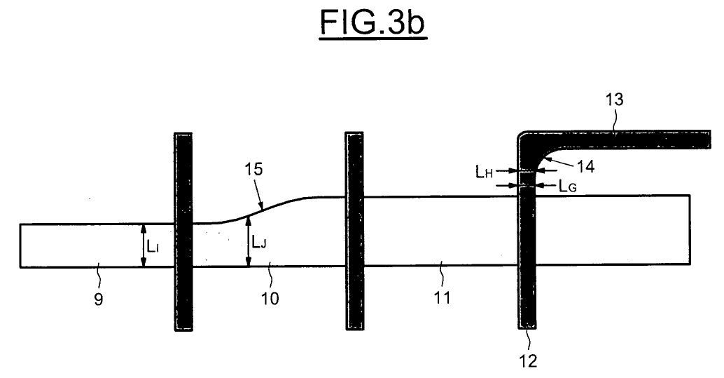

FIG. 4, in which there is an embodiment applied to two sets 16 and 17 of two junctions which are head-to-tail, illustrates an exemplary embodiment which limits the effects of the lateral isolation trench stress within a semiconductor structure. As can be seen, the junction set 16, which is made up by a series of active regions 18, 20 and 22, includes an alternating sequence of source and drain regions produced in an active area. An access via 19 is produced above the active region 18. The same applies to the active region 20 with the access via 21 and to the active region 22 with the access via 23. The active regions 18 and 20 are separated by a gate 24, and the active regions 20 and 22 are separated by a gate 25. The active regions 18 and 22 are biased with a potential Vdd, the active region 20 with a potential Q, while the gates 24 and 25 are biased with a potential Vg.

The other junction set 17 is located proximate to the active region 22 and is arranged in a similar manner. Indeed, it includes an alternating sequence of source, drain and gate regions implanted in active regions 18′, 20′ and 22′ provided with access vias 19′, 21′ and 23′.

To limit rounding of the patterns, all of the structures have the same dimensions, and the contacts between members of a single level are carried over into different levels.

The lateral isolation trench stress could particularly affect the active areas 18 and 22, which would result in dissymmetry of the junctions driven by the gates 24 and 25. The same phenomenon would occur on the junction set 17.

To limit the effect linked to a lateral isolation trench stress, it is desirable to limit the number of lateral isolation trenches and to ensure that the active regions on either side of a gate have the same dimensions.

Two lateral isolation trench sets are normally created, each defining an active area within which the junction sets 16 and 17 will be respectively created.

To prevent the effects of the lateral isolation trench stress, the active areas of the junction sets 16 and 17 are merged, as illustrated in FIG. 4. For this purpose, an active region 27 is created between the active regions 22 and 18′. In practice, instead of defining two active areas which are thereafter joined by an active region 27, a single area is defined which includes the active areas corresponding to the junction sets 16 and 17 and the active region 27.

It should be noted that the active areas 22 and 18′ are biased in the same manner. It is therefore not necessary to control the movement of the charge carriers between these two active regions. However, in order to obtain an even more standardized environment, it would have been possible to add a gate on the active region 20 while allowing it to remain a floating gate, with no modulation of the channel between the active region 22 and 18′ being necessary. The use of a single active area limits the effect of the lateral isolation trench stress at the outer active regions 18 and 22′. The active regions 22 and 18′ are thus spared.

In other words, in order to prevent the effects of a stress of the isolation walls, all of the active areas are grouped together in a single continuous active area. Thus, only a single surface is defined, and the number of lateral isolation trenches is limited. Since the effects of the lateral isolation trench stress appear at the ends of an active area, the number of potentially affected regions is limited to two.

To limit the effect of the lateral trench stress on the outer active regions 18 and 22′, end patterns 29 and 30 are created at the ends of the area delimited by the active regions of the junction sets 16 and 17. These two patterns do not play any active electrical role and form additional transistors. In contrast, by using the same dimensions and the same structures as those already described in the junction sets 16 and 17, they allow the lateral isolation trench stress problems to be absorbed while ensuring that the last active region at each end of the active area, here the active regions 18 and 22′, is perfectly functional. In practice, several patterns are produced at each end, with the effects of the isolation trench stress being experienced at greater distance. Also, for an isolated line, the addition of lines on either side of the isolated line homogenizes the effect of the environment.

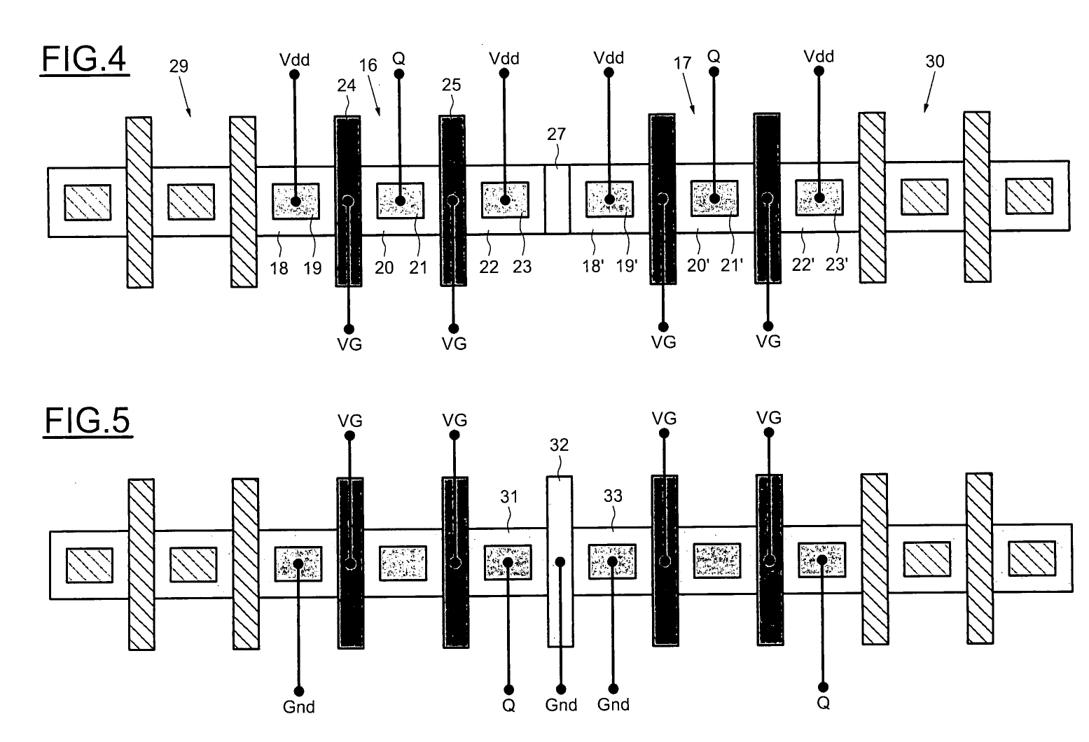

According to another embodiment, FIG. 5 illustrates a device with another way of biasing the junctions. As can be seen, the structure shown in FIG. 5 is similar to that described above with reference to FIG. 4. Indeed, it comprises two sets of junctions each including an alternating sequence of continuous active regions in which the transistors are defined so as to ensure that the active areas on either side of the gate of the transistors have the same dimensions.

However, the active regions 31 and 33 which are opposite the two junction sets are biased differently, and connecting them would modify their effective bias voltage and the operation of the adjoining junctions. To prevent this, a gate 32 is added in order to form a junction between the active regions 31 and 33. By applying an adequate bias voltage, the gate 32 prevents conduction through the channel between the active regions 31 and 33 so as to maintain their respective bias voltages.

In view of the above, the method of designing the transistors of a device such as described above homogenizes the effect of the environment on the various transistors. It also limits the influence of certain negative effects like the influence of lateral isolation trench stress, the rounding of the pattern edges and the proximity effects of the casings.

It may be advantageous to set forth definitions of certain words and phrases used in this patent document. The term “couple” and its derivatives refer to any direct or indirect communication between two or more elements, whether or not those elements are in physical contact with one another. The terms “include” and “comprise,” as well as derivatives thereof, mean inclusion without limitation. The term “or” is inclusive, meaning and/or. The phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following.

What is claimed is:

1. A semiconductor device comprising a plurality of patterns, each pattern comprising at least one field effect transistor, each field effect transistor comprising a source region, a drain region, a channel region, and a gate region formed above the channel region, wherein:
a portion of the plurality of patterns is formed in a single active area of a semiconductor substrate, the area delimited by an isolation region,
one of the source region and the drain region of each adjacent pattern are formed in the active area,
the patterns are laid out in the form of a line, and
the drain and source regions of the field effect transistors of the line have a common first dimension and are separated by gate regions having a common second dimension.

2. The semiconductor device of claim 1, wherein the line comprises:
a first region that is one of a source region and a drain region; and
a second region that is one of a source region and a drain region,
wherein the first region and the second region:
are separated by a distance that is substantially equal to a size of a gate region;
are biased to substantially the same potential; and
share the same active area.

3. The semiconductor device of claim 1, wherein the line includes at least one end pattern at each end of the line.

4. The semiconductor device of claim 3, further including at least one junction located between two adjacent active areas having different polarities.

5. The semiconductor device of claim 4, wherein each junction includes a gate.

6. The semiconductor device of claim 4, wherein the two adjacent active areas are active areas of two adjacent patterns.

7. A method of manufacturing a semiconductor device, the method comprising forming a plurality of patterns in a semiconductor substrate, wherein
each pattern comprises at least one field effect transistor, each field effect transistor comprising a source region, a drain region, a channel region, and a gate region formed above the channel region;
a portion of the plurality of patterns is formed in a single active area of the semiconductor substrate, the area delimited by an isolation region;
one of the source region and the drain region of each adjacent pattern are formed in the active area;
forming a plurality of patterns comprises forming the patterns in the form of a line, the drain and source regions of the field effect transistors of the line having a common first dimension and being separated by gate regions having a common second dimension.

8. The method of claim 7, wherein forming a plurality of patterns further comprises:
forming a first region that is one of a source region and a drain region; and
forming a second region that is one of a source region and a drain region,
wherein the first region and the second region:
are separated by a distance that is substantially equal to a size of a gate region;
are coupled to be biased to substantially the same potential; and
share the same active area.

9. The method of claim 7, wherein forming a plurality of patterns further comprises forming at least one end pattern at each end of the line.

10. The method of claim 9, wherein forming a plurality of patterns further comprises forming at least one junction located between two adjacent active areas having different polarities.

11. The method of claim 10, wherein each junction comprises a gate.

12. A semiconductor device comprising:
an isolation region; and
a plurality of patterns, each pattern comprising at least one field effect transistor, each field effect transistor comprising, a source region, a drain region, a channel region, and a gate region formed above the channel region, wherein
a portion of the plurality of patterns is formed in a single active area of a semiconductor substrate, the area delimited by the isolation region,
one of the source region and the drain region of each adjacent pattern are formed in said active area,
the patterns are laid out in the form of a line, and
the drain and source regions of the field effect transistors of the line have a common first dimension and are separated by gate regions having a common second dimension.

13. The semiconductor device of claim 12, wherein the line comprises:
a first region that is one of a source region and a drain region; and
a second region that is one of a source region and a drain region,
wherein the first region and the second region:
are separated by a distance that is substantially equal to a size of a gate region;
are biased to substantially the same potential; and
share the same active area.

14. The semiconductor device of claim 12, wherein the line includes at least one end pattern at each end of the line.

15. The semiconductor device of claim 14, further including at least one junction located between two adjacent active areas having different polarities.

16. The semiconductor device of claim 15, wherein each junction includes a gate.

17. The semiconductor device of claim 15, wherein the two adjacent active areas are active areas of two adjacent patterns.
